(19) United States
(12) Patent Application Publication
(10) Pub. No.: US 2026/0089890 A1
(43) Pub. Date: Mar. 26, 2026

(54) THERMAL MANAGEMENT FOR POWER SUPPLY DEVICE OF A DATA COMMUNICATION SYSTEM

(71) Applicant: TE Connectivity Solutions GmbH, Schaffhausen (CH)

(72) Inventor: Matthew Ryan Schmitt, Middletown, PA (US)

(21) Appl. No.: 18/892,705

(22) Filed: Sep. 23, 2024

(51) Int. Cl. H05K 7/20; H02G 5/10

(52) U.S. Cl. CPC H05K 7/20418; H02G 5/10; H05K 7/20127; H05K 7/20254; H05K 7/20481; H05K 7/20709

(57) ABSTRACT

A power supply device includes a busbar that includes a support panel, a first busbar element extending along a first side of the support panel and a second busbar element extending along a second side of the support panel. The power supply device includes a shroud surrounding the busbar. The shroud includes shroud walls forming a busbar chamber receiving the busbar. The power supply device includes a heat exchanger coupled to the shroud. The heat exchanger includes an internal portion thermally coupled to the busbar. The heat exchanger includes an external portion exterior of the shroud cooled by convection cooling to dissipate heat from the busbar.

### BACKGROUND OF THE INVENTION

The subject matter herein relates generally to thermal management for a power supply device of a data communication system.

Data communication systems include various components within a data rack, such as a server or network system. The components may be arranged in shelves or trays within the data rack. Power is typically supplied to each of the shells are trays within the data rack by one or more power supply devices, such as a busbar. During use, the temperature of the busbar increases, particularly in the areas where high current loads are attached to the busbar, which may occur at the power shelf that feeds power to the busbar. Current construction of the busbar limits airflow to the internal components of the busbar, which impacts the current carrying capacity of the busbar assembly.

A need remains for a method and device for improved thermal management for a power supply device of a data communication system.

### BRIEF DESCRIPTION OF THE INVENTION

In one embodiment, a power supply device is provided and includes a busbar that includes a support panel, a first busbar element extending along a first side of the support panel and a second busbar element extending along a second side of the support panel. The power supply device includes a shroud surrounding the busbar. The shroud includes shroud walls forming a busbar chamber receiving the busbar. The power supply device includes a heat exchanger coupled to the shroud. The heat exchanger includes an internal portion thermally coupled to the busbar. The heat exchanger includes an external portion exterior of the shroud cooled by convection cooling to dissipate heat from the busbar.

In another embodiment, a power supply device for a data communication system is provided. The power supply device includes a busbar that includes a support panel, a first busbar element extending along a first side of the support panel and a second busbar element extending along a second side of the support panel. The power supply device includes a shroud surrounding the busbar. The shroud includes shroud walls forming a busbar chamber to receive the busbar. The shroud walls include a first side wall, a second side wall, and an end wall opposite a shroud opening configured to receive a power connector of the data communication system. The power supply device includes a first heat exchanger coupled to the first side wall of the shroud. The first heat exchanger includes a first internal portion thermally coupled to the first busbar element. The first heat exchanger includes a first external portion exterior of the shroud cooled by convection cooling to dissipate heat from the first busbar element. The power supply device includes a second heat exchanger coupled to the second side wall of the shroud. The second heat exchanger includes a second internal portion thermally coupled to the second busbar element. The second heat exchanger includes a second external portion exterior of the shroud cooled by convection cooling to dissipate heat from the second busbar element.

In another embodiment, a data communication system is provided and includes a data rack that has a rack space. The data communication system includes equipment trays received in the rack space. The equipment trays include power connectors. The data communication system includes a power supply device coupled to the power connectors to transmit power between the equipment trays. The power supply device includes a shroud coupled to the data rack including shroud walls forming a busbar chamber. The power supply device includes a busbar received in the busbar chamber being electrically connected to the power connectors. The busbar includes a support panel, a first busbar element extending along a first side of the support panel, and a second busbar element extending along a second side of the support panel. The power supply device includes a heat exchanger coupled to the shroud. The heat exchanger includes an internal portion thermally coupled to the busbar and an external portion exterior of the shroud cooled by convection cooling to dissipate heat from the busbar.

### BRIEF DESCRIPTION OF THE DRAWINGS

FIG. 1 is a front view of a portion of a data communication system in accordance with an exemplary embodiment.

FIG. 2 is a rear view of a portion of the data communication system in accordance with an exemplary embodiment.

FIG. 3 is a first side perspective view of the power supply device in accordance with an exemplary embodiment.

FIG. 4 is a second side perspective view of the power supply device in accordance with an exemplary embodiment.

FIG. 5 is a cross-sectional view of the power supply device in accordance with an exemplary embodiment.

FIG. 6 is a side perspective view of the power supply device in accordance with an exemplary embodiment.

FIG. 7 is a cross-sectional view of the power supply device 100 in accordance with an exemplary embodiment.

### DETAILED DESCRIPTION OF THE INVENTION

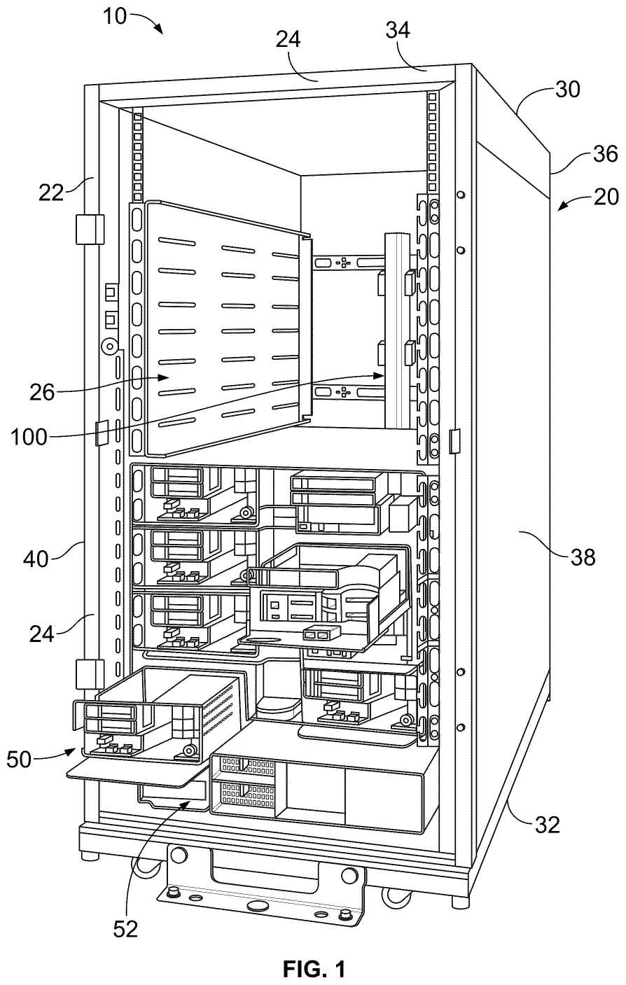

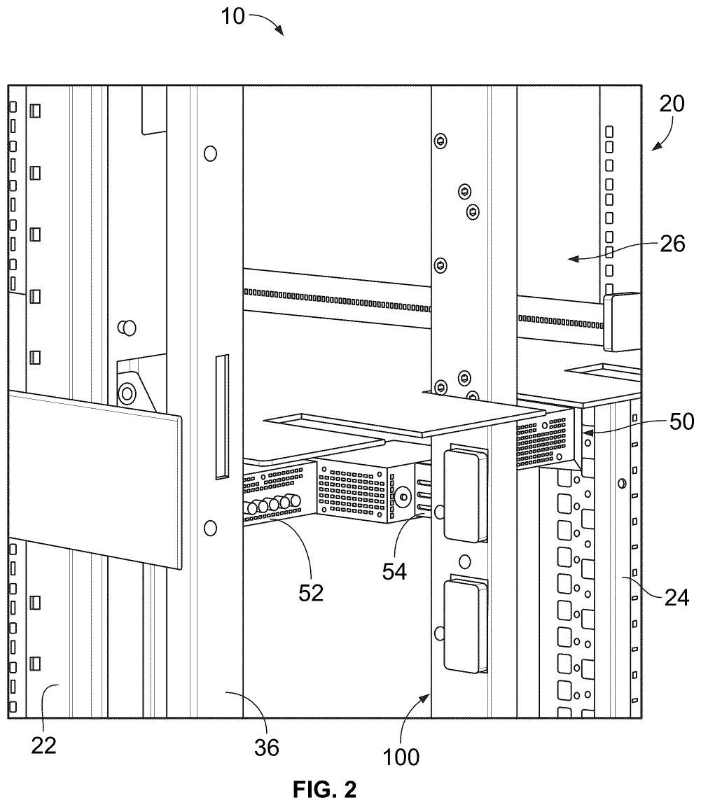

FIG. 1 is a front view of a portion of a data communication system 10 in accordance with an exemplary embodiment. FIG. 2 is a rear view of a portion of the data communication system 10 in accordance with an exemplary embodiment. In an exemplary embodiment, the data communication system 10 is a server rack housing network or server components. However, the data communication system 10 may be utilized in other applications in alternative embodiments.

The data communication system 10 includes a data rack 20 having a rack frame 22 holding electrical components 50. The rack frame 22 includes frame members 24, coupled together, forming the rack frame 22. The frame members 24 may include posts, beams, cross members, panels, walls or other components. The rack frame 22 may form a cabinet to surround the electrical components 50. The data rack 20 may be a server rack. The rack frame 22 of the data rack 20 forms a rack space 26, which may be subdivided or partitioned into multiple slots that receive corresponding electrical components 50. In various embodiments, the data rack 20 is generally rectangular or box-shaped. For example, the data rack 20 includes a top 30, a bottom 32, a front 34, a rear 36 and opposite sides 38, 40. The data rack 20 may be open at the front 34 to receive the electrical components 50. For example, the electrical components 50 may be plugged into the data rack 20 through the front 34.

The electrical components 50 are fixed to the data rack 20. For example, the electrical components 50 may be received in corresponding slots of the rack space 26 and secured to the rack frame 22. The electrical components 50 may be stacked in the data rack 20. In various embodiments, the electrical components 50 may include one or more patch panels, switches, servers, routers, firewalls, and the like. In an exemplary embodiment, the electrical components 50 include equipment trays 52 received in corresponding equipment slots of the rack frame 22. The equipment trays 52 may include compute trays, switch trays, power supply trays, and the like. The electrical components 50 may include cooling components, such as fans, to cool the equipment trays 52 or other components of the data communication system 10.

In an exemplary embodiment, the data communication system 10 includes a power supply device 100 configured to supply power to the electrical components 50. In the illustrated embodiment, the power supply device 100 is coupled to the rear 36 of the data rack 20. The power supply device 100 extends vertically behind the equipment slots of the rack frame 22 to allow electrical connection to each of the equipment trays 52 to transfer power to/from the various equipment trays 52. For example, when the equipment trays 52 are plugged into the data rack 20, the equipment trays 52 are electrically connected to the power supply device 100. In an exemplary embodiment, the equipment trays 52 include power connectors 54 (FIG. 2) coupled to the power supply device 100.

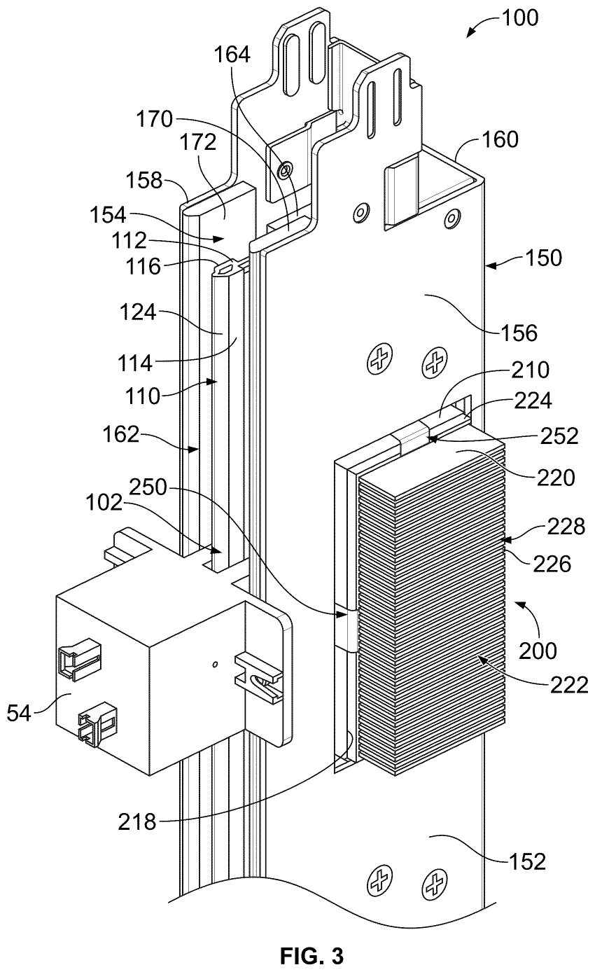

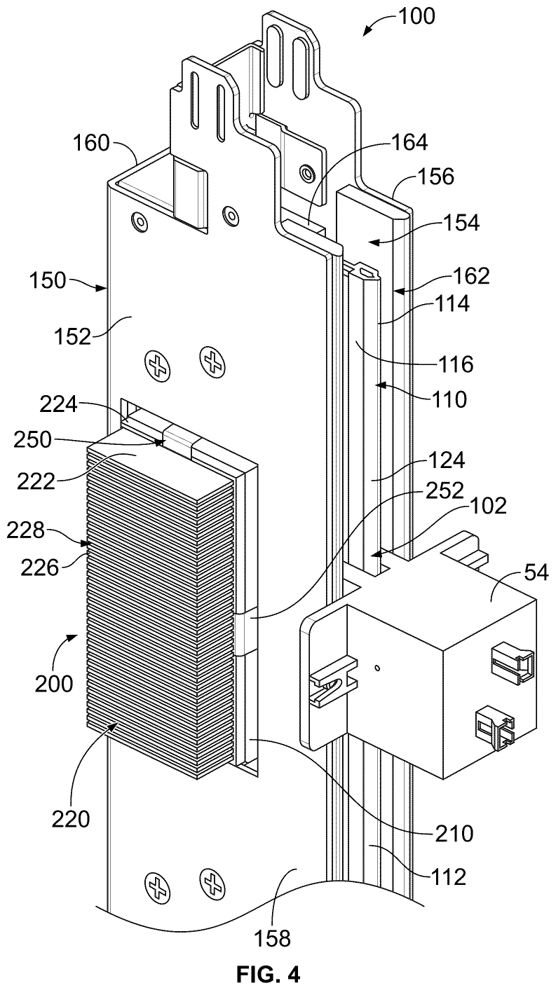

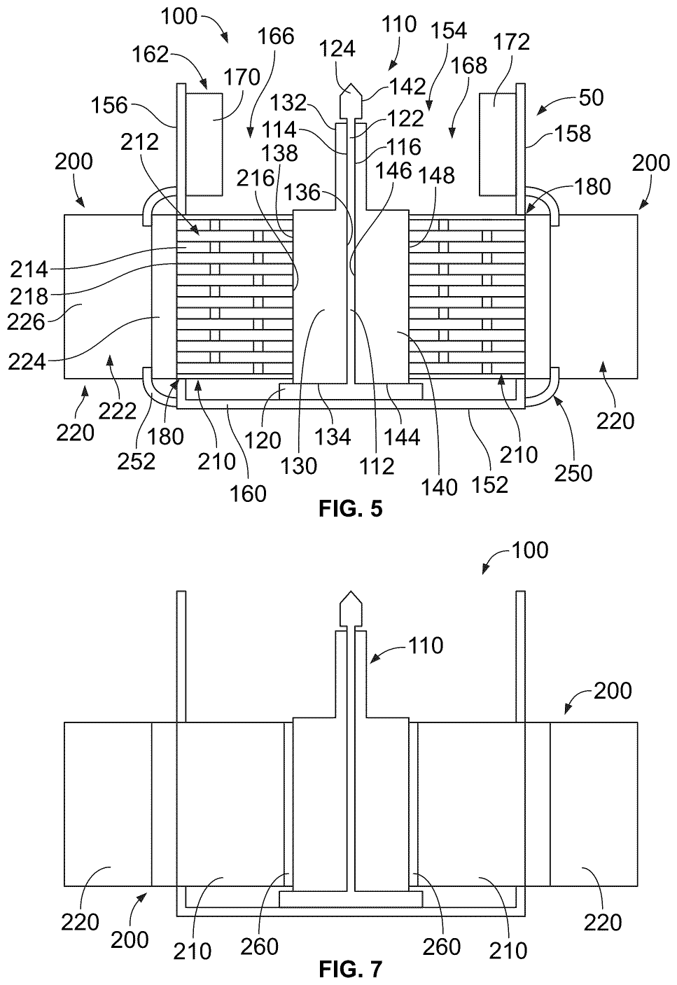

FIG. 3 is a first side perspective view of the power supply device 100 in accordance with an exemplary embodiment. FIG. 4 is a second side perspective view of the power supply device 100 in accordance with an exemplary embodiment. FIG. 5 is a cross-sectional view of the power supply device 100 in accordance with an exemplary embodiment. FIGS. 3 and 4 illustrate an exemplary power connector 54 coupled to the power supply device 100 at a mating zone 102. In an exemplary embodiment, multiple mating zones 102 may be located along the power supply device 100 to mate with multiple power connectors 54.

The power supply device 100 includes a busbar 110, a shroud 150 surrounding the busbar 110, and one or more heat exchangers 200 coupled to the busbar 110 to dissipate heat from the busbar 110. In the illustrated embodiment, the power supply device 100 includes heat exchangers 200 on the opposite sides of the power supply device 100. In various embodiments, the power supply device 100 may include a plurality of the heat exchangers 200 located vertically along the power supply device 100 to dissipate heat from the busbar 110 at different heights along the busbar 110, such as at different mating zones 102.

The busbar 110 is electrically conductive in configured to collect and distribute electrical power for the data communication system 10, such as to distribute electrical power to the various equipment trays 52 (FIG. 1). The busbar 110 is used for high current power distribution along the power supply device. The busbar 110 is configured to be mated to multiple power connectors 54 to transmit power between the various power connectors 54.

In an exemplary embodiment, the busbar 110 includes a support panel 112, a first busbar element 130 extending along a first side 114 of the support panel 112, and a second busbar element 140 extending along a second side 116 of the support panel 112. The support panel 112 is manufactured from a dielectric material, such as a plastic material. The support panel 112 electrically isolates the first busbar element 130 from the second busbar element 140. The first busbar element 130 may be a positive or feed conductor for the busbar 110 in the second busbar element 130 may be a negative or returned conductor for the busbar 110.

The support panel 112 of includes a base 120, a main panel 122 extending from the base 120 and a cap 124 at the distal end of the support panel 112. The first and second busbar elements 130, 140 are attached to opposite sides of the main panel 122. The base 120 is located rearward of the first and second busbar elements 130, 140. The cap 124 extends forward of the first and second busbar elements 130, 140. The cap 124 may be a touch safe feature to prevent inadvertent touching of the high current busbar 110. In the illustrated embodiment, the cap 124 is wedge-shaped at the distal end to guide mating of the power connector 54 with the busbar 110.

The first busbar element 130 is a metal conductor. For example, the first busbar element 130 may be a copper or aluminum conductor. In an exemplary embodiment, the first busbar element 130 is a conductive plate extending between a front 132 and the rear 134. The first busbar element 130 includes an inner surface 136 attached to the support panel 112 and an outer surface 138 opposite the inner surface 136. The power connector 54 is configured to electrically connect to the outer surface 138 of the first busbar element 130 at a mating interface. In an exemplary embodiment, multiple power connectors 54 may electrically connect to the first busbar element 130 at vertically staged mating interfaces along the height of the first busbar element 130. In various embodiments, the first busbar element 130 may be stamped and have different thicknesses. For example, the first busbar element 130 may be thinner at the front 132 and thicker at the rear 134.

The second busbar element 140 is a metal conductor. For example, the second busbar element 140 may be a copper or aluminum conductor. In an exemplary embodiment, the second busbar element 140 is a conductive plate extending between a front 142 and the rear 144. The second busbar element 140 includes an inner surface 146 attached to the support panel 112 and an outer surface 148 opposite the inner surface 146. The support panel 112 is located between the inner surfaces 136, 146 of the first and second busbar elements 130, 140. The power connector 54 is configured to electrically connect to the outer surface 148 of the second busbar element 140 at a mating interface. In an exemplary embodiment, multiple power connectors 54 may electrically connect to the second busbar element 140 at vertically staged mating interfaces along the height of the second busbar element 140. In various embodiments, the second busbar element 140 may be stamped and have different thicknesses. For example, the second busbar element 140 may be thinner at the front 142 and thicker at the rear 144.

The shroud 150 is used to support and/or surround the busbar 110 to isolate the busbar 110 and prevent inadvertent touching of the high current busbar 110 to prevent damage and/or injury. The shroud 150 includes a plurality of shroud walls 152 and form a busbar chamber 154 that receives the busbar 110. In an exemplary embodiment, the shroud walls 152 are stamped and formed from a metal sheet into a predetermined shape. In an exemplary embodiment, the shroud 150 is C-shaped including sides extending between an open end and a closed-end. The shroud 150 is configured to extend vertically along the rear of the data rack 20 to interface with the equipment trays 52 plugged into the data rack 20.

In an exemplary embodiment, the shroud walls 150 to include a first side wall 156, a second side wall 158, and an end wall 160 extending between the first and second side walls 156, 158. A shroud opening 162 is located opposite the end wall 160 between the first and second side walls 156, 158. In the illustrated embodiment, the shroud opening 162 is located at the front of the shroud 150 and the end wall 160 is located at the rear of the shroud 150. The shroud opening 162 is configured to receive the power connector 54. For example, the mating end of the power connector 54 may be plugged into the shroud opening 162 to electrically connect to the busbar 110.

The busbar 110 is configured to be positioned generally in the center of the busbar chamber 154. For example, the busbar 110 may be generally centered between the first side wall 156 and the second side wall 158. In an exemplary embodiment, the shroud 150 includes standoffs 164 extending from the first and second side walls 156, 158 to position the busbar 110 in the busbar chamber 154. The standoffs 164 may be secured to the first and second side walls 156, 158 using fasteners or other securing means. The standoffs 164 are manufactured from a dielectric material to electrically isolate the busbar 110 from the shroud walls 150. The busbar 110 is held in the busbar chamber 154 spaced apart from the first and second side walls 156, 158 by the standoffs 164 such that first and second gaps 166, 168 are formed between the first and second busbar elements 130, 140 and the corresponding first and second side walls 156, 158. The mating end of the power connector 54 is configured to be received in the first and second gaps 166, 168 to electrically connect power terminals of the power connector 54 two the first and second busbar elements 130, 140.

In an exemplary embodiment, the shroud 150 includes ground terminals 170, 172 along the first and second side walls 156, 158 at the front of the shroud 150 to electrically connect to the power connector 54. The ground terminals 170, 172 extend vertically along the shroud 150. The ground terminals 170, 172 may be located immediately rearward of the shroud opening 162. The ground terminals 170, 172 may be electrically connected to ground contacts of the power connector 54 when the power connector 54 is plugged into the power supply device 100.

In an exemplary embodiment, the shroud walls 152 include openings 180 that receive the heat exchangers 200. For example, the first and second side walls 156, 158 may each have openings 180 that receive the corresponding first and second heat exchangers 200 at the first and second sides of the power supply device 100. The openings 180 allow the heat exchangers 200 to pass into the interior of the shroud 150 to directly interface with the busbar 110. The openings 180 allow the heat exchangers 200 to pass to the exterior of the shroud 150 to allow convection cooling of the heat exchangers 200 to dissipate heat from the power supply device 100. For example, the heat exchangers 200 dissipate heat from the busbar 110 to lower the operating temperature of the busbar 110, thus increasing the current carrying capacity of the busbar 110. The heat exchangers 200 dissipate heat from the busbar 110 at a location proximate to the mating zone, which is an area of the busbar 110 susceptible to increased heat load during operation. By lowering the temperature of the busbar 110, the busbar 110 is able to handle larger input amperage allowing connection of higher power electrical components 50 and/or a greater number of electrical components 50 in the data communication system 10.

In an exemplary embodiment, each heat exchanger 200 includes an internal portion 210 and an external portion 220. The internal portion 210 is configured to be thermally coupled to the busbar 110. For example, the internal portion is located in the corresponding gap 166, 168 between the busbar 110 and the corresponding side walls 156, 158. The external portion 220 is located exterior of the shroud 150. For example, the external portion 220 passes through the opening 180 to the exterior of the shroud 150 for connection cooling by airflow flowing around the power supply device 100. In various embodiments, the heat exchanger 200 is a multipiece heat exchanger wherein the internal portion 210 is separate and discrete from the external portion 220. In other various embodiments, the heat exchanger 200 may be a single piece heat exchanger wherein the internal portion 210 and the external portion 220 are an integral, unitary structure.

In an exemplary embodiment, electrical isolation is provided between the heat exchanger 200 and the busbar 110 to avoid exposing the electrical current outside of the shroud 150. For example, the internal portion 210 may include an electrical isolator. In an exemplary embodiment, the electrical isolator is a thermally conductive insulator that readily allows thermal conduction to efficiently dissipate heat from the busbar 110 while maintaining electrical isolation from the busbar 110. In various embodiments, the internal portion 210 may include a non-electrically conductive thermal interface material at the interface between the heat exchanger 200 and the busbar 110. The non-electrically conductive thermal interface material may be a thin layer, sheet, pad, or coating between the heat exchanger 200 and the busbar 110. The non-electrically conductive thermal interface material may be applied to the internal portion 210 and/or the busbar 110. In various embodiments, the internal portion 210 may be manufactured from a thermally conductive but electrically insulative material, such as a ceramic material. In various embodiments, the internal portion 210 may be a block or sheet of material providing an interface between the busbar 110 and the external portion 220.

In an exemplary embodiment, the internal portion 210 includes a thermal bridge 212. The thermal bridge 212 includes a stack of interleaved plates 214. The interleaved plates 214 may be held by a frame or other holding member to position the interleaved plates 214 relative to each other. The interleaved plates 214 may be sandwiched together in the stack to allow thermal transfer between the interleaved plates 214. The interleaved plates 214 may be movable relative to each other, such as to conform to the busbar 110 and/or the external portion 220. In an exemplary embodiment, the internal portion 210 extends between an interior surface 216 and an exterior surface 218. The interior surface 216 faces the busbar 110. The interior surface 216 may directly interface with the outer surface of the corresponding busbar element 130, 140. The interior surface 216 may be generally planar. The exterior surface 218 faces the external portion 220. The exterior surface 218 may be generally planar. However, the exterior surface may be nonplanar, such as having a stepped interface in other various embodiments.

The external portion 220 is located exterior of the shroud 150. The external portion 220 is configured to be cooled by airflow flowing around the outside of the shroud 150. In an exemplary embodiment, the external portion 220 includes a heat sink 222. The heat sink 222 includes a base 224 extending from the internal portion 210. The heat sink 222 includes heat fins 226 extending from the base 224 and airflow gaps 228 between the heat fins 226. The airflow gaps 228 allow airflow between the heat fins 226 four conductive cooling of the heat fins 226. In various embodiments, the heat fins 226 are planar plate-like structures. However, the heat fins 226 may have other shapes in alternative embodiments, such as cylindrical posts or other shapes. In an exemplary embodiment, the heat fins 226 are formed integral with the base 224, such as being extruded, molded, cast, or otherwise formed from a unitary, monolithic structure. In alternative embodiments, the heat sink 222 may be manufactured from a stack of individual plates of various widths to form the airflow gaps 228. In various embodiments, the external portion 220 may be manufactured from a metal material, such as copper or aluminum that is highly thermally conductive. In alternative embodiments, the external portion 220 may be manufactured from an electrically insulating, thermally conductive material to avoid power transfer to the exterior of the shroud 150. For example, the external portion 220 may be manufactured from a ceramic material. In alternative embodiments, the external portion 220 may have an outer layer or coating that is electrically insulating.

In the illustrated embodiment, the heat fins 226 extend front to rear to allow airflow through the airflow gaps 228 from the front to the rear of the heat exchanger 200. In alternative embodiments, the heat fins 226 may extend top to bottom to allow airflow from the top to the bottom of the heat exchanger 200. The direction or orientation of the heat fins 226 may corresponds to an airflow direction from a cooling device, such as a fan integrated into the data communication system 10.

Other types of heat transfer devices may be used in alternative embodiments other than the heat sink 222. For example, the external portion 220 of the heat exchanger 200 may include a cold plate cooled by a cooling fluid, such as a liquid cooling fluid.

In an exemplary embodiment, the heat exchanger 200 is coupled to the shroud 150. For example, the power supply device 100 includes a heat exchanger support assembly 250 that supports the heat exchanger 200 relative to the shroud 150. In an exemplary embodiment, the heat exchanger support assembly 250 is coupled to the shroud wall 152 to support the heat exchanger 200 independent of the busbar 110. The heat exchanger support assembly 250 may include support beams, fasteners, clips, latches, or other elements to physically support the heat exchanger 200 relative to the shroud 150. In an exemplary embodiment, the heat exchanger support assembly 250 includes one or more compression elements 252 that press the heat exchanger 200 inward toward the busbar 110. For example, the compression elements 252 may include springs or other types of biasing elements that provide an inward biasing force to press the heat exchanger 200 into physical contact with the busbar 110. The inward biasing force ensures efficient thermal transfer between the heat exchanger 200 in the busbar 110.

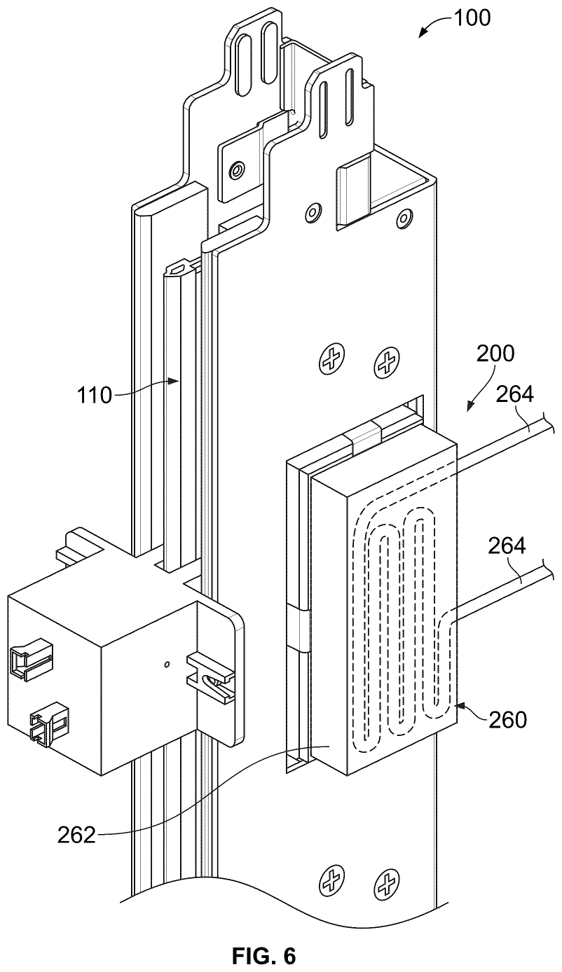

FIG. 6 is a side perspective view of the power supply device 100 in accordance with an exemplary embodiment. FIG. 6 illustrates the heat exchanger 200 including a cold plate 260 at the external portion 220. The cold plate 260 includes a plate member 262 and coolant lines 264 coupled to the plate member 262 two circulated cooling fluid through the cold plate 260. The cold plate 260 is thermally coupled to the internal portion 210 to dissipate heat from the busbar 110.

FIG. 7 is a cross-sectional view of the power supply device 100 in accordance with an exemplary embodiment. FIG. 7 illustrates the heat exchanger 200 including a non-electrically conductive thermal interface material 260 at the internal portion 210. The thermal interface material 260 electrically isolates the heat exchanger 200 from the busbar 110.

It is to be understood that the above description is intended to be illustrative, and not restrictive. For example, the above-described embodiments (and/or aspects thereof) may be used in combination with each other. In addition, many modifications may be made to adapt a particular situation or material to the teachings of the invention without departing from its scope. Dimensions, types of materials, orientations of the various components, and the number and positions of the various components described herein are intended to define parameters of certain embodiments, and are by no means limiting and are merely exemplary embodiments. Many other embodiments and modifications within the spirit and scope of the claims will be apparent to those of skill in the art upon reviewing the above description. The scope of the invention should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, in the following claims, the terms “first,” “second,” and “third,” etc. are used merely as labels, and are not intended to impose numerical requirements on their objects. Further, the limitations of the following claims are not written in means - plus-function format and are not intended to be interpreted based on 35 U.S.C. § 112(f), unless and until such claim limitations expressly use the phrase “means for” followed by a statement of function void of further structure.

What is claimed is:

1. A power supply device comprising:
a busbar including a support panel, a first busbar element extending along a first side of the support panel and a second busbar element extending along a second side of the support panel;
a shroud surrounding the busbar, the shroud including shroud walls forming a busbar chamber receiving the busbar; and
a heat exchanger coupled to the shroud, the heat exchanger including an internal portion thermally coupled to the busbar, the heat exchanger including an external portion exterior of the shroud cooled by convection cooling to dissipate heat from the busbar.

2. The power supply device of claim 1, wherein the shroud walls include an opening, the heat exchanger passing through the opening.

3. The power supply device of claim 1, wherein the internal portion of the heat exchanger is electrically isolated from the busbar.

4. The power supply device of claim 1, wherein a gap is provided between the busbar and the shroud walls, the internal portion of the heat exchangers spanning the gap between the busbar and the shroud walls.

5. The power supply device of claim 1, wherein the external portion of the heat exchanger includes one of a heat sink or a cold plate.

6. The power supply device of claim 1, wherein the internal portion of the heat exchanger includes a nonconductive thermal interface material between the busbar and the external portion of the heat exchanger.

7. The power supply device of claim 1, wherein the internal portion of the heat exchanger includes a nonconductive thermal bridge.

8. The power supply device of claim 7, wherein the thermal bridge includes a stack of interleaved plates movable relative to each other, the interleaved plates being manufactured from a ceramic material.

9. The power supply device of claim 1, wherein the internal portion of the heat exchanger is compressible.

10. The power supply device of claim 1, wherein the external portion of the heat exchanger includes heat fins with airflow gaps between the heat fins to allow airflow between the heat fins for conductive cooling of the heat fins.

11. The power supply device of claim 1, wherein the heat exchanger is a first heat exchanger thermally coupled to the first busbar element, the power supply device further comprising a second heat exchanger thermally coupled to the second busbar element and extending from an opposite side of the shroud from the first heat exchanger.

12. The power supply device of claim 1, wherein the busbar includes a mating zone configured to be mated to a power connector, the heat exchanger aligned with the mating zone, rearward of the mating zone, to dissipate heat from the mating zone of the busbar.

13. The power supply device of claim 1, wherein the heat exchanger includes a compression element configured to press the heat exchanger into thermal engagement with the busbar.

14. A power supply device for a data communication system, the power supply device comprising:
a busbar including a support panel, a first busbar element extending along a first side of the support panel and a second busbar element extending along a second side of the support panel;
a shroud surrounding the busbar, the shroud including shroud walls forming a busbar chamber receiving the busbar, the shroud walls including a first side wall, a second side wall, and an end wall opposite a shroud opening configured to receive a power connector of the data communication system;
a first heat exchanger coupled to the first side wall of the shroud, the first heat exchanger including a first internal portion thermally coupled to the first busbar element, the first heat exchanger including a first external portion exterior of the shroud cooled by convection cooling to dissipate heat from the first busbar element; and
a second heat exchanger coupled to the second side wall of the shroud, the second heat exchanger including a second internal portion thermally coupled to the second busbar element, the second heat exchanger including a second external portion exterior of the shroud cooled by convection cooling to dissipate heat from the second busbar element.

15. The power supply device of claim 14, wherein the first shroud wall include a first opening and the second shroud wall includes a second opening, the first heat exchanger passing through the first opening, the second heat exchanger passing through the second opening.

16. The power supply device of claim 14, wherein gaps are provided between the first busbar element and the first shroud wall and the second busbar element and the second shroud wall, the first internal portion spanning the gap between the first busbar element and the first shroud wall, the second internal portion spanning the gap between the second busbar element and the second shroud wall.

17. The power supply device of claim 14, wherein the external portion of the heat exchanger includes one of a heat sink or a cold plate.

18. A data communication system comprising:
a data rack having a rack space;
equipment trays received in the rack space, the equipment trays including power connectors; and
a power supply device coupled to the power connectors to transmit power between the equipment trays, the power supply device including a shroud coupled to the data rack including shroud walls forming a busbar chamber, the power supply device including a busbar received in the busbar chamber being electrically connected to the power connectors, the busbar including a support panel, a first busbar element extending along a first side of the support panel, and a second busbar element extending along a second side of the support panel, the power supply device including a heat exchanger coupled to the shroud, the heat exchanger including an internal portion thermally coupled to the busbar and an external portion exterior of the shroud cooled by convection cooling to dissipate heat from the busbar.

19. The data communication system of claim 18, wherein the shroud walls include an opening, the heat exchanger passing through the opening.

20. The data communication system of claim 18, wherein the internal portion of the heat exchanger is electrically isolated from the busbar.
